(19) United States
(12) Patent Application Publication
(10) Pub. No.: US 2011/0274836 A1
(43) Pub. Date: Nov. 10, 2011

(54) REMOVAL OF TRAPPED SILICON WITH A CLEANING GAS

(75) Inventors: Dung Huu Le, San Jose, CA (US); James L'Heureux, Santa Clara, CA (US); Jeffrey S. Sullivan, Castro Valley, CA (US); Xiaoxiong Yuan, San Jose, CA (US)

(73) Assignee: APPLIED MATERIALS, INC., Santa Clara, CA (US)

(21) Appl. No.: 12/774,318

(22) Filed: May 5, 2010

(51) Int. Cl. C23C 16/44; B05C 11/00; B01J 19/00

(52) U.S. Cl. 427/248.1; 422/177; 422/173

(57) ABSTRACT

Embodiments of the present invention relate to apparatus and methods of preventing build-up of explosive material in vacuum forelines of deposition systems. A cleaning gas such as nitrogen trifluoride (NF₃) may be introduced into a particulate collection device including a catchpot having a configuration comprising a sloped interior surface area that maximizes the amount of reactive silicon-containing particles that are exposed to and react with the cleaning gas stream to form silicon tetrafluoride (SiF₄) and other non-reactive by-products. The degree of slope of the interior surface area may be based upon the angle of repose of the silicon-containing particles. The gaseous silicon tetrafluoride (SiF₄) and other non-reactive by-products can flow out of the catchpot and into the exhaust stream towards a vacuum pump. The apparatus and method may also avoid accumulation of highly reactive and highly explosive particulates in catchpots.

### BACKGROUND OF THE INVENTION

1. Field of the Invention

Embodiments of the present invention generally relate to an apparatus and method of managing particles and material accumulation in exhaust components used in deposition systems. More specifically, embodiments of the present invention relate to an apparatus and method of preventing build-up of explosive material in vacuum forelines of chemical vapor deposition systems.

2. Description of the Related Art

Typically, chemical vapor deposition (CVD), atomic layer deposition (ALD) and other vapor phase deposition process will generate highly reactive silicon powder by-products. These by-products may comprise primarily silicon (Si), but other silicon-containing compounds such as SiO and SiH may also be present. In particular, thin film solar bottom cell intrinsic silicon and N-doped silicon deposition processes, commonly used in solar applications, tend to form silicon particles which may exit the deposition chamber and collect in the vacuum exhaust line of the chamber, commonly called the foreline, and possibly make their way to the vacuum pump(s). If many deposition cycles are run in a process chamber using silane or other similar compounds, silicon-containing powder may accumulate in the vacuum forelines between the chamber and the vacuum pumps. After many deposition cycles, a significant amount of surface area inside the foreline pipes may be coated with this highly reactive material. If the highly reactive dust or particulate is subsequently exposed to air, such as during maintenance, there can be a violent reaction and even an explosion. Moreover, in some cases, the silicon-containing particulates may travel downstream and clog the vacuum pumps. When the pump is opened to atmospheric conditions during maintenance, the silicon-containing particulates may ignite.

Several methods have been used to prevent a build-up of or help dispose of explosive silicon powder in the vacuum forelines of chemical vapor deposition (CVD) systems. For example, one solution has been to clean the foreline with NF₃, fluorine, or other gases with an etching property. This solution has been implemented in amorphous silicon deposition processes with some success. However, microcrystalline silicon deposition processes generate more powder than can effectively be etched away in a cleaning step. Another drawback to cleaning the foreline with an etchant is that it is difficult to determine how far down the foreline the silicon is etched and removed. Furthermore, the lines may get hot from the etching process, leading to a potentially explosive situation if unreacted powder remains in the foreline. Another solution which has been proposed includes collecting the dust and mixing it with trifluourotri-chloro-ethane liquid to render a slurry that is then distilled. This solution, however, may not comport with environmental regulations. Yet another solution has been to connect a catch pot at the bottom of the vacuum foreline just upstream of the vacuum pump to collect the reactive powder. However, after many deposition cycles, the catch pot gets full and needs to be emptied out. Emptying out the catch pot is a dangerous procedure because the powder collected is very fine and is highly reactive, which can lead to explosions and the generation of significant amounts of heat as the highly reactive powder is oxidized. Moreover, the catch pot needs to emptied from time to time, which leads to process down time.

Therefore, there is a need for a method and apparatus of safely and effectively handling or disposing of highly reactive silicon containing dust which forms inside vacuum exhaust forelines.

### SUMMARY OF THE INVENTION

The present invention generally relates to an apparatus and method of managing particles and material accumulation in exhaust components used in deposition systems. More specifically, embodiments of the present invention relate to an apparatus and method of preventing build-up of explosive material in vacuum forelines of chemical vapor deposition systems.

In one embodiment, a particulate collection device is provided comprising a pot assembly having a collection region. The pot assembly comprises at least one sloped surface disposed within the collection region of the pot assembly, wherein the sloped surface is configured to receive particulates from a foreline that is fluidly coupled to a pump and a substrate processing chamber, and one or more walls disposed proximate to the sloped surface to form a channel, wherein the channel is configured to direct a flowing cleaning gas over the particulates disposed on the sloped surface.

In another embodiment, a particulate collection device is provided, comprising a pot assembly having a collection region The pot assembly comprises a bicone at an upper portion of the collection region of the pot assembly, wherein the bicone has an outer surface that is configured to receive at least a first amount of particulates from a foreline that is fluidly coupled to a pump and a substrate processing chamber, wherein the outer surface of the bicone is sloped at an angle from a horizontal equal to or greater than the angle of repose of the particulates. The pot assembly also comprises a first stepped surface surrounding a second surface of the bicone and spaced in relation to the first surface, wherein the first stepped surface is configured to receive at least a second amount of particulates received from the foreline, and wherein the first stepped surface and the second surface of the bicone are spaced apart to form a gap. The pot assembly further comprises a cone comprising a second stepped surface that is sloped at an angle from the horizontal, wherein the second stepped surface is configured to receive at least a third amount of the particulates received from the foreline, and wherein the cone is coupled to the bicone. The pot assembly also comprises a channel proximate the second stepped surface, wherein a gas may flow through the channel and the gap to react with the particulates disposed on the first and second stepped surfaces.

In another embodiment, a method of processing a substrate in a deposition chamber is provided, comprising depositing a layer on a substrate in a processing region of a deposition chamber, wherein by-products are produced in a foreline or a processing region of the deposition chamber during the process of depositing the layer, catching a portion of the by-products in a processing region of a catchpot that is fluidically connected to the foreline, and converting at least a portion of the by-products disposed in the catchpot to a gaseous phase by flowing a cleaning gas over a portion of the by-products disposed on an angled surface that is disposed in the processing region of the catchpot.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a cross-sectional view of a catchpot according to one embodiment of the present invention;

FIG. 1B is a three-dimensional perspective view of a catchpot according to one embodiment of the present invention;

FIG. 1C is a three-dimensional cross-sectional view of a catchpot according to one embodiment of the present invention;

FIG. 1D is a close-up side cross-sectional view of a catchpot according to one embodiment of the present invention;

FIG. 1E is a close-up side cross-sectional view of a catchpot according to one embodiment of the present invention;

FIG. 2 is a schematic cross-sectional view of a plasma enhanced chemical vapor deposition (PECVD) chamber which may be used with a catchpot according to one embodiment of the present invention in relation thereto; and

FIG. 3 is a cross-sectional view of a catchpot according to one embodiment of the present invention.

### DETAILED DESCRIPTION

Embodiments described herein provide a method and apparatus for cleaning exhaust components found in a vacuum deposition system, such as particulate collection devices, including catchpots connected to vacuum forelines in a deposition system, such as a chemical vapor deposition system. More specifically, embodiments of the present invention relate to a method and apparatus of preventing build-up of a highly reactive material in catchpots coupled to a vacuum foreline connected to a chemical vapor deposition system. In one embodiment, a catchpot is provided having an interior surface area which maximizes the rate of reaction between silicon particulates landing on the interior surface area of the catchpot and nitrogen trifluoride flowing through the catchpot.

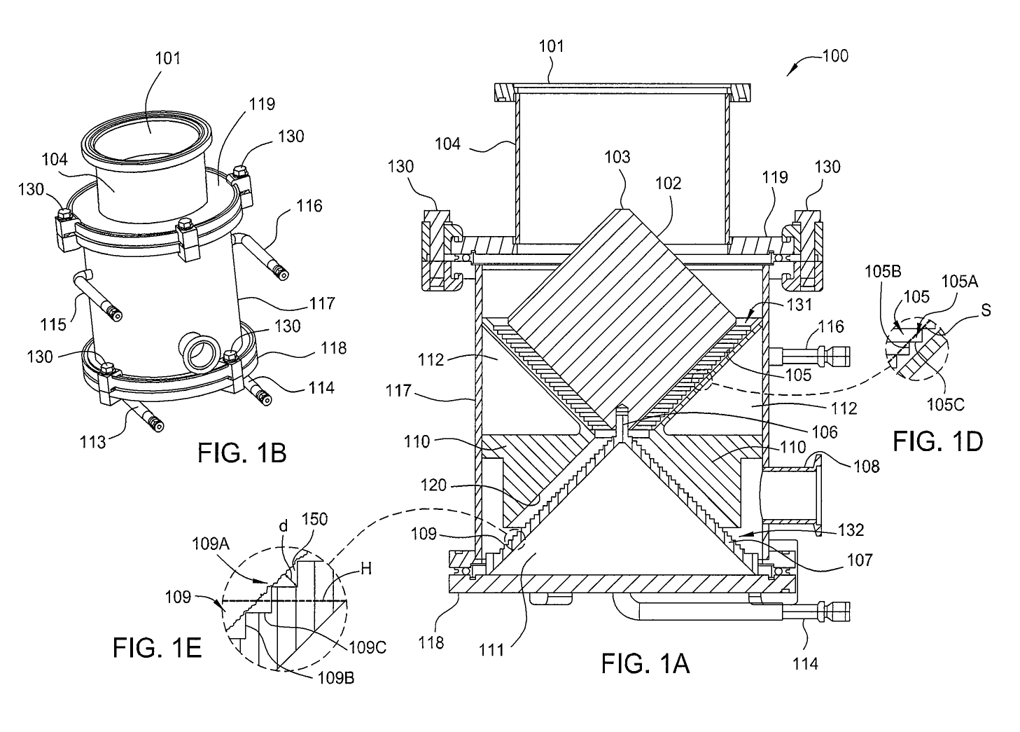

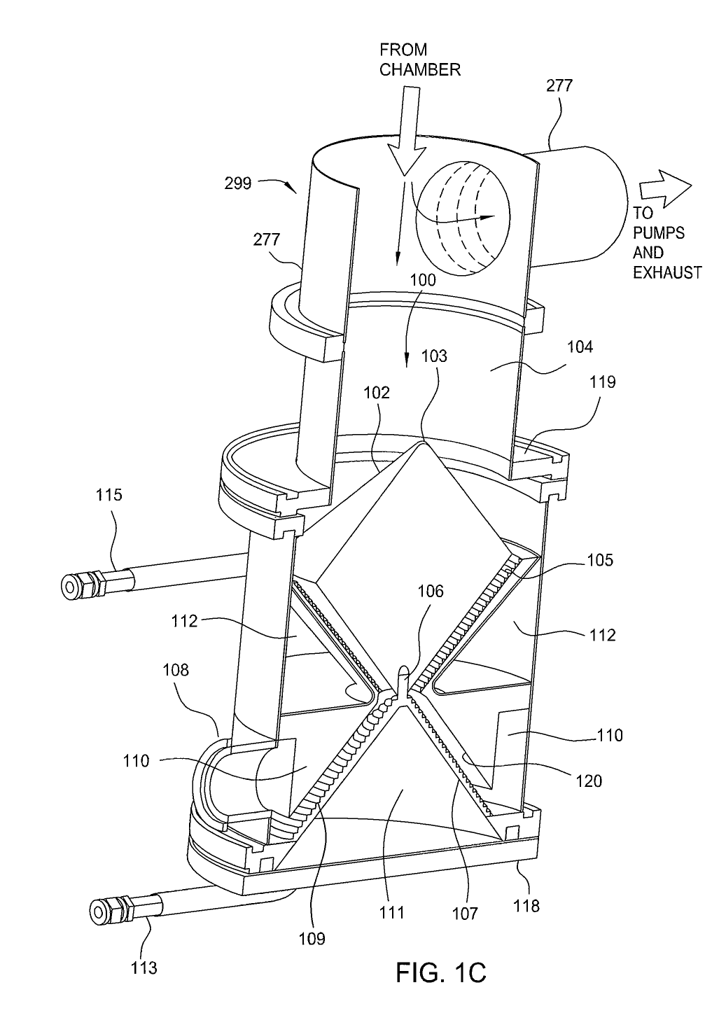

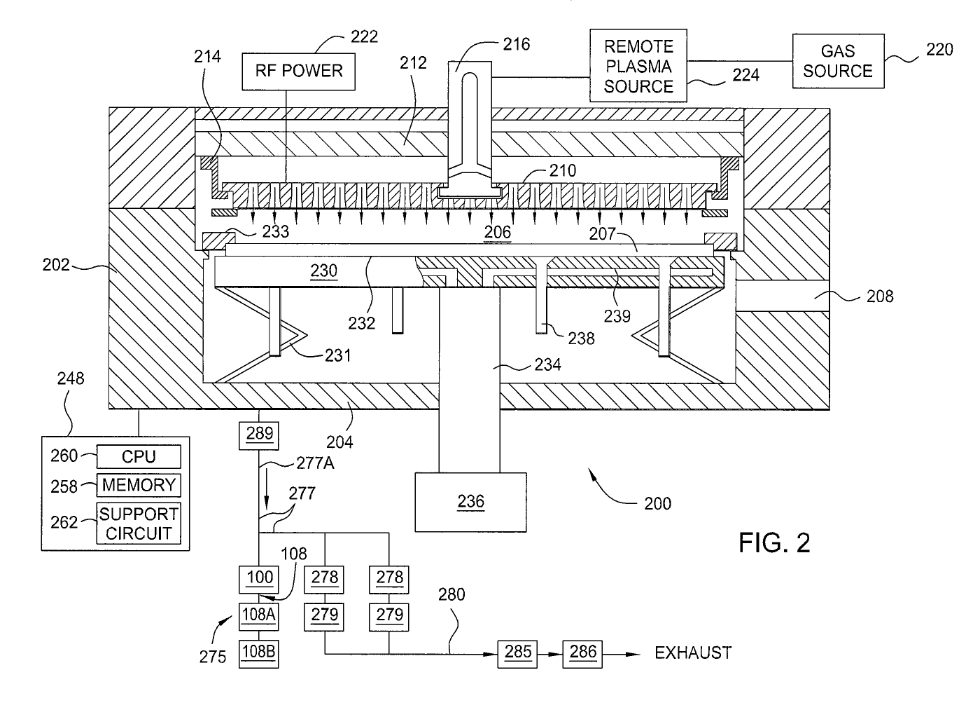

FIG. 1A illustrates a cross-sectional view of one embodiment of a catchpot 100 having a collection region comprising an upper interior reaction surface area 131 generally resembling an inverted cone and a lower reaction surface area 132 generally resembling an upright cone. FIG. 1B shows an isometric view of catchpot 100 as seen from above. As shown in FIG. 1B, catchpot 100 may have a generally cylindrical shaped exterior. A bottom 118 and lid 119 of catchpot 100 may be attached to a middle section 117 of catchpot 100 by use of coupling mechanisms 130, which may comprise, for example, conventional bolts and clamping devices. The lid 119, bottom 118 and middle section 117 of catchpot 100 may be made of 316L stainless steel. FIG. 1C shows a three-dimensional cross-sectional view of the catchpot 100 shown in FIG. 1A. Catchpot 100 comprises an exhaust port or an opening 101 at a top portion thereof which may be fluidly connected to a chamber foreline (see foreline 277 connected to catchpot 100 in FIG. 2).

Generally, a cleaning gas such as nitrogen trifluoride (NF₃) may be introduced through a port 108 located near the bottom of catchpot 100 to react with silicon-containing powder collected in catchpot 100. As shown in FIGS. 1A and 1B, the interior of catchpot 100 may comprise several conical surfaces, some of which may have steps 105A (FIG. 1D) thereon, for retaining and dispersing the powder collected within catchpot 100. The steps 105A may comprise a horizontal surface, or bottom 105C, and a vertical surface, or side 105B. “Horizontal” as used herein, is shown by horizontal line H in FIG. 1E. Dispersing the powder may increase the rate of reaction. Gaseous products of the reaction between the gas and the silicon-containing powder may exit catchpot 100 through opening 101. As explained in more detail below, catchpot 100 may also provide means for cooling one or more of the conical surfaces to absorb some of the heat released during the reaction.

As shown in FIG. 2, a chamber foreline 277 is connected to chamber 200 and carries exhaust from the chamber 200 to vacuum pumps 278 and 279. Foreline 277 may make a 90 degree turn region 299 (FIG. 1C) at a portion thereof after which point it may connect directly to catchpot 100 through opening 101 or to a line which may be in fluid communication with opening 101 in catchpot 100.

In general, the one or more processing by-products coming out of chamber 200 may include gas molecules, partially reacted precursor materials (some of it in particulate form, e.g., silicon-containing powder), un-reacted vapor phase compounds, and/or other reaction by-products. Referring to FIG. 2, exhaust including these processing by-products may flow out of processing chamber 200 and into foreline 277. The processing by-products may then flow into a first section 277A of the foreline 277 in which heavier particulates, such as powder comprising highly reactive silicon and SiO with SiH groups, may flow into catchpot 100 through opening 101.

As the silicon-containing powder or particles fall into catchpot 100 through opening 101, they may land on a cone distributor 102 in the interior of catchpot 100, as shown in FIG. 1A. A lower cone 107 may be located under cone distributor 102 and may support cone distributor 102 inside catchpot 100. The silicon-containing particles may hit cone distributor 102 at a high speed as a result of the flow of gas in the foreline 277 created by the vacuum pumps 278 and 279 and gravity. Cone distributor 102 may be in the shape of a bicone, resembling a geometric shape formed by joining two identical right circular cones base to base. Cone distributor 102 can be manufactured almost entirely from 316L stainless steel. In another embodiment, the two circular cones forming the bicone of cone distributor 102 may have different heights. Cone distributor 102 may be placed within catchpot 100 such that the upper apex 103 of cone distributor 102 may be located in the center of opening 101 as viewed from above (i.e., on a horizontal plane). As shown more clearly in FIG. 1C, upper apex 103 of cone distributor 102 may be located within channel 104 leading into catchpot 100 (i.e., on a vertical plane), or below the bottom of channel 104. As shown in FIG. 1A, cone distributor 102 may be supported by a structure protruding from an apex of lower cone 107. The supporting structure may be a screw or a pin 106, which may screw into or mate with the bottom apex of cone distributor 102. It should be noted that other methods of supporting cone distributor 102 on the apex of lower cone 107 may be used, so long as they provide enough structural support to hold cone distributor 102 at the desired angle and can bear the weight of cone distributor 102. In some embodiments, a longer pin 106 may be used in order to more firmly support cone distributor 102 and maintain it at the desired angle within catchpot 100. As shown in FIGS. 1A and 1C, the top half of cone distributor 102 may have a smooth outer surface angled at about 45 degrees, so that when silicon-containing particles fall into catchpot 100 and onto cone distributor 102 they disperse downwards onto a first stepped inner surface 105 of catchpot 100. It should be noted that the angle from vertical of the top half of cone distributor 102 may be greater than 45 degrees or less than 45 degrees, depending on the angle of “repose” of the particles that may rest on the surface of the top half of cone distributor 102. For example, an incline of 45 degrees may be used because silicon-containing particles have an angle of repose of about 45 degrees. In another example, if the silicon-containing particles are wet (thereby having a larger angle of repose), a steeper incline (or an angle from vertical less than 45 degrees) may be desired so that the silicon-containing particles travel down the surface of the cone distributor 102 more easily, and thus do not collect on the surface and obstruct the gap formed between the adjacently positioned components. The incline angle of cone distributor 102 may range from about 40 degrees to about 60 degrees, or from about 40 degrees to about 50 degrees. The top half of cone distributor 102 should have a sufficiently steep slope and have a smoothly finished surface such that particles landing thereon are evenly dispersed down onto the first stepped inner surface 105 of catchpot 100.

As shown in FIGS. 1A and 1C, first stepped inner surface 105 may be inclined parallel to the bottom outer surface of cone distributor 102. First stepped inner surface 105 may resemble an upside down right circular cone open at both ends thereof, similar to a funnel. First stepped inner surface 105 may comprise steps at right angles all the way down first stepped inner surface 105 and along the entire circumference thereof. The ratio of the length of the side 1058 of each step 105A to the bottom 105C of each step 105A (also known as the rise to run ratio) can be about 2:3. However, other ratios may be used depending on the angle of repose of the particles disposed over the first stepped inner surface 105 of the catchpot 100. For example, for particles having an angle of repose of about 45 degrees, such as silicon-containing particles, the rise to run ratio may be 1:1 (which would correspond to an average angle of incline for first stepped inner surface 105 of about 45 degrees (average angle of incline is equivalent to arctangent (average rise/average run)). The average angle of incline for a stepped surface, as used herein, corresponds to the slope of line S in FIG. 1D. For particles having a smaller angle of repose, the ratio of side length to bottom length of each step may be smaller than 2:3. For particles having a larger angle of repose, a side length to bottom length ratio (rise to run ratio) greater than 2:3 may be used for each step. The average angle of incline formed by the steps of first stepped inner surface 105 may range from about 40 degrees to about 60 degrees, or from about 40 degrees to about 50 degrees. As the particles fall on each step, they build up on the step forming a mound until the slope of the mound reaches the angle of repose for the particulate material, at which point the particles fall down to the next step down. In some embodiments, the ratio of side 1058 length to bottom 105C length may be different from step to step. The steps should be shallow enough so that all of the silicon-containing particles 150 (FIG. 1E) collected on each step fully react with the cleaning gas flowing into catchpot 100 and no portions of collected silicon-containing particles are inaccessible by the cleaning gas. In other words, the depth d shown in FIG. 1E should not be so large that portions of the accumulated particles do not come into contact with gas flowing proximate steps 105A. The depth d will depend on the length of the rise and the run, as well as the rise to run ratio. This ensures a high rate of conversion and minimizes the amount of unreacted silicon-containing particles remaining in catchpot 100. For a catchpot 100 having a volume of about 50 cubic centimeters, steps measuring about 2 mm high and 3 mm across may be used. In other embodiments, steps having a rise to run ration of about 5 mm by 5 mm may be used.

As the silicon-containing particles fall onto first stepped inner surface 105, they will accumulate on each step. Once a sufficient amount of silicon-containing particles has accumulated on each step, the particles will begin to slide down onto the step below. In this manner, the particles may make their way down catchpot 100. Once the silicon-containing particles reach the bottom step of the first stepped inner surface 105, they begin a similar sliding process down the second stepped outer surface 109 of lower cone 107. As seen in FIGS. 1A and 1C, second stepped outer surface 109 may be inclined parallel to the bottom surface 120 of interior wall 110. Second stepped outer surface 109 may comprise steps at right angles all the way down second stepped outer surface 109 and along the entire circumference thereof. Similar to first stepped inner surface 105, the ratio of the length of the side 109B of each step 109A to the bottom 109C of each step 109A can be about 2:3. However, other ratios may be used depending on the angle of repose of the particles disposed over the second stepped outer surface 109 of the catchpot 100 in order to maximize the surface area of silicon-containing particles exposed to the cleaning gas. For example, for particles having an angle of repose of about 45 degrees, such as silicon-containing particles, the rise to run ratio of steps of second stepped outer surface 109 may be 1:1 (which would correspond to an average angle of incline for second stepped outer surface 109 of about 45 degrees (average angle of incline is equivalent to arctangent (average rise/average run)). In another example, for particles having a lower angle of repose, the ratio of side length to bottom length of each step (the rise to run ratio) may be smaller than 2:3. For particles having a higher angle of repose, a side length to bottom length ratio greater than 2:3 may be used for each step. The average angle of incline formed by the steps of second stepped outer surface 109 may range from about 40 degrees to about 60 degrees, or from about 40 degrees to about 50 degrees. In some embodiments, the rise to run ratio may be different from step to step. For a catchpot 100 having a volume of about 50 cc, steps measuring about 2 mm high and 3 mm across may be used. In other embodiments, steps having a rise to run ratio of about 5 mm by 5 mm may be used. The average angle of incline of second stepped outer surface 109 may be the same as or different from the average angle of incline of first stepped inner surface 105. Also, the average rise to run ratio for the steps of first stepped inner surface 105 may be different from that of the steps of second stepped outer surface 109.

An inlet port 108 may be located near the bottom of catchpot 100 for introducing a cleaning gas, such as nitrogen trifluoride (NF₃), from a cleaning gas source 108B into catchpot 100 to react with the silicon-containing particles collected inside the catchpot. The cleaning gas source 108B may be coupled with the inlet port 108 and may be configured to deliver a cleaning gas such as nitrogen trifluoride (NF₃). While the discussion herein refers to nitrogen trifluoride (NF₃) gas as the cleaning gas, it should be understood that other cleaning gases may be used to remove the collected particulate material (e.g., silicon particles), and thus is not intended to be limiting as to the scope of the invention described herein. In some examples, other cleaning gases which may be used may to remove silicon particles include gas containing fluorine, sulfur, chlorine, oxygen, and/or nitrogen. However, when a cleaning process is being run in the process chamber, it may not be necessary to deliver nitrogen trifluoride (NF₃) through inlet port 108 because nitrogen trifluoride (NF₃) may already be flowing into foreline 277 from the chamber 200 (see FIG. 2). Inlet port 108 may be coupled to a cleaning gas line which may be coupled with a cleaning gas source 108B (such as nitrogen trifluoride (NF₃) gas). A remote plasma source (RPS) 108A may be coupled with the cleaning gas line at a location between the cleaning gas source 108B and inlet port 108. For a catchpot 100 having a volume of about 50 cc, a 5 kW RF source may be used. The RF power required for the process will vary depending on the chamber volume. For a catchpot 100 having a volume of about 50 cc, nitrogen trifluoride (NF₃) may be delivered at a flowrate of about 8 slm. In other embodiments, a flowrate of nitrogen trifluoride (NF₃) of about 3 slm for a 50 cc catchpot 100 may suffice for full conversion of the silicon-containing particles collected inside the catchpot. In other embodiments, the flowrate of nitrogen trifluoride (NF₃) delivered to catchpot 100 having a volume of about 50 cc may range between 3 slm and 8 slm. Catchpot 100 may vary in size, and in some embodiments may be smaller than, or larger than 50 cc. Generally, the flowrate of nitrogen trifluoride (NF₃) may be about 160 sccm per 1 cc volume of catchpot 100.

As the nitrogen trifluoride (NF₃) flows into catchpot 100 through inlet port 108, it occupies the empty volume inside catchpot 100 and flows up towards opening 101 through channels created by the gaps between lower cone 107 and surface 120, and cone distributor 102 and first stepped inner surface 105. The pressure within catchpot 100 may be about 5 to 10 Torr, or at least greater than the pressure in the foreline 277 at the opening 101. As the nitrogen trifluoride (NF₃) flows up the channels of catchpot 100, it may react with the silicon-containing particles collected on the steps of second stepped outer surface 109 and first stepped inner surface 105 to form silicon tetrafluoride (SiF₄) and other reaction by-products. In one embodiment, the stepped surfaces within catchpot 100 are configured to promote the turbulent flow of the cleaning gas, such as nitrogen trifluoride (NF₃) gas, to promote better mixing and thus improve the reaction rate with the silicon-containing particles collected on the steps and reduce the cleaning time. Furthermore, the channels formed by the gaps between the cone distributor 102 and first stepped inner surface 105, and lower cone 107 and surface 120 may be sufficiently narrow so as to encourage turbulent flow of the nitrogen trifluoride (NF₃) gas. These channels may also optimize the residence time of the nitrogen trifluoride (NF₃) gas within catchpot 100 to increase the rate of reaction. The channels may be optimized such that fluorine radicals can access silicon-containing particles easily and a suitable gas pressure can be maintained at the remote plasma source (RPS) 108A.

Silicon tetrafluoride (SiF₄) and any other gaseous by-products of the reaction, along with any unreacted nitrogen trifluoride (NF₃), may then flow out of catchpot 100 through opening 101 into the foreline (277 in FIG. 2) and downstream towards vacuum pumps 278 and 279. It is generally desirable that the flow of the cleaning gas from the catch pot 100 is not high enough to cause the cleaning gases and reaction by-products to back-flow into the chamber 200. The reaction between the nitrogen trifluoride (NF₃) and silicon-containing particles that are collected in catchpot 100 may be maximized such that most if not all of the silicon-containing particles are converted to non-reactive products, leaving little to no reactive silicon-containing particles within catchpot 100. Any remaining silicon-containing particles may accumulate at the bottom of catchpot 100, proximate the bottom steps of second stepped outer surface 109, which are near the bottom 118. These accumulated unreacted silicon-containing particles may be removed when catchpot 100 is changed during maintenance. However, assuming complete conversion, there should be no silicon-containing particles remaining at the bottom of catchpot 100. At the very least, any accumulation of reactive silicon-containing particles will occur at a much slower rate than in a standard collection device, which merely collects the particles (e.g., silicon-containing material) in an open vessel (e.g., barrel), or regions of the foreline 277, without introducing any cleaning gases therein.

Catchpot 100 can be manufactured almost entirely from 316L stainless steel. Because the reaction between the silicon-containing particles and the nitrogen trifluoride (NF₃) is exothermic, first stepped inner surface 105 and second stepped outer surface 109 may reach very high temperatures (e.g., in the order of about 600° C.), in some cases exceeding the melting point of stainless steel. Therefore, catchpot 100 may include a cooling system to keep the catchpot components, particularly the surfaces 105 and 109, where reactions take place, from heating up too much.

As shown in FIGS. 1A-1C, catchpot 100 may include a space or volume proximate to first stepped inner surface 105 and a space or volume proximate to second stepped outer surface 109 which may be filled with a cooling liquid, such as water, to absorb some of the heat generated by the reactions occurring at or near the stepped surfaces. Lower cone 107 may be a hollow cone comprising an interior volume 111 which may be filled with a cooling liquid, such as water, to cool second stepped outer surface 109. As shown in FIG. 1C, interior volume 111 may comprise a majority of the volume within lower cone 107. In other embodiments, the size and shape of interior volume 111 may be manipulated depending on the amount of cooling needed for second stepped outer surface 109. For example, lower cone 107 may be manufactured to be only partially hollow or sections within lower cone 107 may be walled off so that interior volume 111 is reduced, depending on the amount of cooling needed for second stepped outer surface 109. In another embodiment, interior volume 111 may comprise channels running under second stepped outer surface 109. As shown more clearly in FIG. 1B, cooling water may be introduced into interior volume 111 through piping 113 connected to the bottom of catchpot 100. The cooling water may exit interior volume 111 through piping 114 also connected to the bottom of catchpot 100. First stepped inner surface 105 may be cooled by filling a space or interior volume 112 just underneath it with cooling water. The size and shape of interior volume 112 may be manipulated as described above for interior volume 111 depending on the amount of cooling needed for first stepped inner surface 105. For example, if less cooling is desired, interior volume 112 may be reduced. As shown more clearly in FIG. 1B, cooling water may be introduced into interior volume 112 through piping 115 connected to a top portion of catchpot 100. The cooling water may exit interior volume 112 through piping 116 also connected to catchpot 100 at a top portion thereof. In this manner, cooling water may be circulated through interior volumes 111 and 112. Piping 113, 114, 115, and 116 may be made of stainless steel and may be connected to one or more heat exchangers and/or recirculation pumps so that the cooling water can be recirculated back into interior volumes 111 and 112. The amount of cooling water flowing through piping 113 and 115 may be controlled by valves, which may be connected to a controller which may monitor temperatures inside catchpot 100. For example, temperatures at first stepped inner surface 105 and second stepped outer surface 109 may be measured and a controller may adjust the flow and or temperature of cooling water entering interior volumes 111 and 112. The control system may include a central processing unit (CPU), a memory, and support circuits.

In this manner, instead of filling a catchpot with reactive silicon-containing powder, a cleaning gas such as nitrogen trifluoride (NF₃) may be introduced into a catchpot having a configuration that advantageously maximizes the amount of reactive silicon-containing particles that are exposed to and react with the nitrogen trifluoride (NF₃) gas stream to form silicon tetrafluoride (SiF₄) and other non-reactive by-products. The gaseous silicon tetrafluoride (SiF₄) and other non-reactive by-products can flow into the exhaust stream and travel to the vacuum pumps. The vacuum pumps may then deliver the pumped gases to some subsequent scrubber and/or chemical abatement systems prior to being exhausted to the environment. This avoids the risk of having to dispose of reactive silicon-containing material accumulated in the catchpot.

FIG. 2 is a schematic cross-sectional view of a plasma enhanced chemical vapor deposition (PECVD) chamber 200 that can be used with one embodiment of a catchpot as described herein. One suitable PECVD chamber is available from Applied Materials, Inc., located in Santa Clara, Calif. It is contemplated that other deposition chambers, including those from other manufacturers, may be utilized to practice the present invention.

Chamber 200 generally includes walls 202, a bottom 204, a showerhead 210, and substrate support 230 which define a processing volume 206. The process volume may be accessed through a valve 208 such that the substrate may be transferred in and out of the chamber 200. The substrate support 230 includes a substrate receiving surface 232 for supporting a substrate 207 and stem 234 coupled to a lift system 236 to raise and lower the substrate support 230. A shadow ring 233 may be optionally placed over the periphery of the substrate 207. Lift pins 238 are moveably disposed through the substrate support 230 to move a substrate to and from the substrate receiving surface 232. The substrate support 230 may also include heating and/or cooling elements 239 to maintain the substrate support 230 at a desired temperature. The substrate support 230 may also include grounding straps 231 to provide RF grounding at the periphery of the substrate support 230.

The showerhead 210 is coupled to a backing plate 212 at its periphery by a suspension 214. The showerhead 210 may also be coupled to the backing plate 212 by one or more center supports 216 to help prevent sag and/or control the straightness/curvature of the showerhead 210. A gas source 220 is coupled to the backing plate 212 to provide gas through the backing plate 212 and through the showerhead 210 to the substrate receiving surface 232. An RF power source 222 is coupled to the backing plate 212 and/or to the showerhead 210 to provide a RF power to the showerhead 210 so that an electric field is created between the showerhead 210 and the substrate support 230 so that a plasma may be generated from the gases between the showerhead 210 and the substrate support 230. Various RF frequencies may be used, such as a frequency between about 0.3 MHz and about 200 MHz. In one embodiment the RF power source is provided at a frequency of 13.56 MHz.

A remote plasma source 224, such as an inductively coupled remote plasma source, may also be coupled between the gas source 220 and the backing plate 212. Between processing substrates, a cleaning gas may be provided to the remote plasma source 224 so that a remote plasma is generated and provided to clean chamber components. The cleaning gas may be further excited by the RF power source 222 provided to the showerhead. Suitable cleaning gases include but are not limited to NF₃, F₂, Cl₂ and SF₆.

A controller 248 may be coupled to the processing chamber 200. The controller 248 includes a central processing unit (CPU) 260, a memory 258, and support circuits 262. The controller 248 is utilized to control the process sequence, regulating the gas flows from the gas source 220 into the chamber 200 and controlling power supply from the RF power source 222 and the remote plasma source 224. The CPU 260 may be of any form of a general purpose computer processor that can be used in an industrial setting. The software routines can be stored in the memory 258, such as random access memory, read only memory, floppy or hard disk drive, or other form of digital storage. The support circuits 262 are conventionally coupled to the CPU 260 and may comprise cache, clock circuits, input/output subsystems, power supplies, and the like. The software routines, when executed by the CPU 260, transform the CPU into a specific purpose computer (controller) 248 that controls the processing chamber 200 such that the processes, such as described above, are performed in accordance with the present invention. The software routines may also be stored and/or executed by a second controller (not shown) that is located remotely from the processing chamber 200.

As described with reference to FIG. 2, a chamber foreline valve 289, such as a pneumatic valve, may be located downstream of chamber 200 so that when the valve is shut, there is no fluidic communication between the chamber 200 and the section of foreline 277 downstream of the chamber foreline valve 289. Chamber foreline valve 289 keeps materials in the foreline 277 from contaminating the chamber 200. The volume in the section of foreline 277 downstream of chamber foreline valve 289 will be under vacuum conditions, so that any gases in that section will distribute and fill up the volume available, so that no mixing is required, but is certainly an option.

Any solid particulates in foreline 277 may be deposited in catch pot 100, which may be placed at the bottom of foreline 277 just upstream of the vacuum pumps. The material which accumulates in catch pot 100 will consist primarily of highly reactive silicon-containing particles. Any gases in foreline 277 will then flow towards one or more vacuum pumps. The vacuum pumps 278 and 279 may be in a stacked pump configuration, as shown in FIG. 2. For example, one or more roots blowers (vacuum pump 278) may each be placed in line with one or more mechanical pumps (vacuum pump 279). Exhaust line 280 may carry exhaust from vacuum pumps 279 to a collection vessel 285. As with the gas supply lines, instead of all lines from vacuum pumps 279 joining to form a single exhaust line 280 that is connected to the collection vessel 285, there may be a separate line from each vacuum pump 279 to the collection vessel 285. The vapor phase exhaust can then be diverted from the collection vessel 285 into abatement unit 286 to minimize or eliminate, such as by making inert, any residual by-products that may be hazardous air pollutants before they can be exhausted to the atmosphere.

One example of a deposition process that can be used to form a silicon-containing layer on a substrate, such as a p-type microcrystalline silicon layer, may comprise delivering a gas mixture of hydrogen gas to silane (SiH₄) gas in a ratio of about 200:1 or greater to the processing region disposed over the substrate. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. The flow rates in the present disclosure are expressed as sccm per interior chamber volume. The interior chamber volume is defined as the volume of the interior of the chamber which a gas can occupy. An RF power between about 50 milliwatts/cm² and about 700 milliwatts/cm² may be provided to the showerhead 210. The RF powers in the present disclosure are expressed as Watts supplied to an electrode per substrate surface area. The pressure in the processing volume 206 of the chamber may be maintained between about 1 Torr and about 100 Torr, preferably at about 12 Torr. The pressure in the processing volume 206 is generally controlled by the delivery of the process gases (e.g., silane, hydrogen) from a process gas source, such as gas source 220, and the exhaust of the processing by-products to the vacuum pumps connected to the foreline 277 and exhaust system 275. The deposition rate of the p-type microcrystalline silicon contact layer may be about 10 Å/min or more. The p-type microcrystalline silicon contact layer has a crystalline fraction between about 20 percent and about 80 percent, preferably between 50 percent and about 70 percent. Other examples of other silicon deposition processes performed in a deposition chamber that may be used in conjunction with one or more of the embodiments described herein are disclosed in the commonly assigned U.S. Pat. No. 7,582,515, which is herein incorporated by reference in its entirety.

The substrate processing methods described herein may be especially useful for depositing layers on large area substrates used to form solar cells, such as substrates measuring 2.2 meters by 2.6 meters. The substrate processing methods may be useful for thin film solar processes and batch crystalline silicon processes.

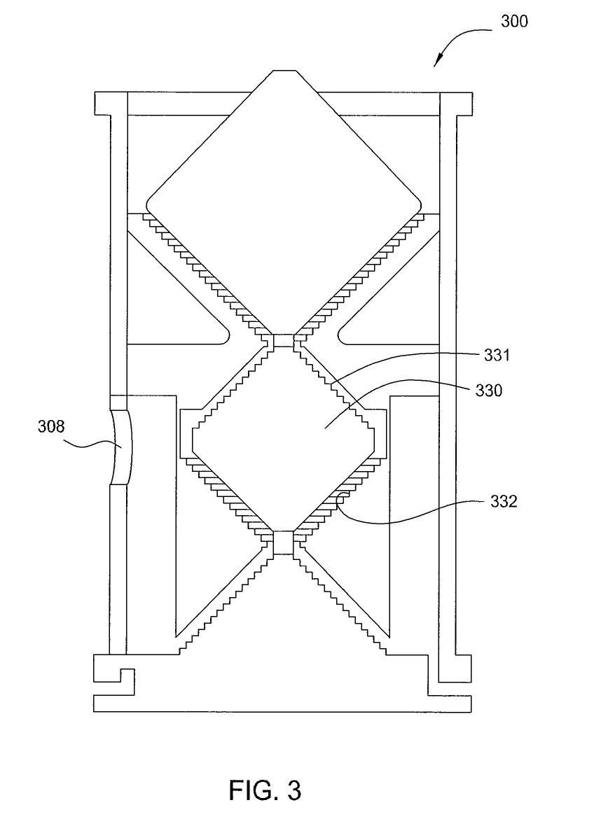

FIG. 3 shows a configuration for another embodiment of a catchpot according to the present invention. This embodiment operates similarly to catchpot 100 in FIGS. 1A-1C, but has an additional bicone 330 in the middle section thereof, thus increasing the amount of reaction surface area by adding two additional stepped surfaces 331 and 332. The additional bicone 330 also increases the residence time and turbulence of the cleaning gas flowing within catchpot 300, thus improving the reaction rate between the silicon-containing particles collected within catchpot 300 and the nitrogen trifluoride (NF₃) introduced at inlet port 308. It should be noted that the catchpot of the present invention is not limited to the configurations shown at FIGS. 1A-1C and 3. Other configurations of conical surface areas having stepped surfaces may be used.

Thus, an apparatus and method of preventing build-up of explosive material in vacuum forelines of chemical vapor deposition systems is provided. Nitrogen trifluoride (NF₃) may be introduced into a catchpot having a configuration that maximizes the amount of reactive silicon-containing particles that are exposed to and react with the nitrogen trifluoride (NF₃) gas stream to form silicon tetrafluoride (SiF₄) and other non-reactive by-products. The gaseous silicon tetrafluoride (SiF₄) and other non-reactive by-products can flow out of the catchpot and into the exhaust stream towards a vacuum pump. The apparatus and method also avoid accumulation of highly reactive and highly explosive particulates in catch pots which then need to be carefully disposed of.

While the foregoing is directed to embodiments of the present invention, other and further embodiments of the invention may be devised without departing from the basic scope thereof, and the scope thereof is determined by the claims that follow.

1. A particulate collection device comprising:
a pot assembly having a collection region, wherein the pot assembly comprises:
at least one sloped surface disposed within the collection region of the pot assembly, wherein the at least one sloped surface is configured to receive particulates from a foreline that is fluidly coupled to a pump and a substrate processing chamber; and
one or more walls disposed proximate to the at least one sloped surface to form a channel, wherein the channel is configured to direct a flowing cleaning gas over the particulates disposed on the at least one sloped surface.

2. The particulate collection device of claim 1, wherein the at least one sloped surface is sloped at an angle equal to or greater than the angle of repose of the particulates.

3. The particulate collection device of claim 1, wherein at least a portion of the at least one sloped surface comprises at least one step.

4. The particulate collection device of claim 1, wherein at least a portion of the at least one sloped surface comprises at least one step, wherein the at least one step has a rise to run ratio to minimize the maximum depth of the particulates disposed on the step.

5. The particulate collection device of claim 1, wherein the at least one sloped surface has an average angle of incline of about 40 degrees to about 60 degrees.

6. The particulate collection device of claim 1, wherein the pot assembly further comprises an inlet port that is fluidly coupled to the collection region of the pot assembly, wherein the inlet port is fluidly coupled to a source of the cleaning gas.

7. The particulate collection device of claim 6, wherein the source of the cleaning gas is configured to deliver a gas comprising nitrogen trifluoride (NF₃).

8. The particulate collection device of claim 1, wherein the pot assembly further comprises an exhaust port that is fluidly coupled to the collection region of the pot assembly.

9. The particulate collection device of claim 8, wherein the exhaust port is configured to introduce a cleaning gas comprising nitrogen trifluoride (NF₃) into the pot assembly.

10. The particulate collection device of claim 1, wherein the pot assembly further comprises a system for cooling the at least one sloped surface comprising:
at least one volume proximate the at least one sloped surface, wherein the at least one volume is isolated from the at least one sloped surface;
at least one inlet port for flowing a cooling water into the at least one volume; and
at least one outlet port for flowing the cooling water out of the at least one volume.

11. A particulate collection device comprising:
a pot assembly having a collection region, wherein the pot assembly comprises:
a bicone at an upper portion of the collection region of the pot assembly, wherein the bicone has an outer surface that is configured to receive at least a first amount of particulates from a foreline that is fluidly coupled to a pump and a substrate processing chamber, wherein the outer surface of the bicone is sloped at an angle from a horizontal equal to or greater than the angle of repose of the particulates;
a first stepped surface surrounding a second surface of the bicone and spaced in relation to the first surface, wherein the first stepped surface is configured to receive at least a second amount of particulates received from the foreline, wherein the first stepped surface and the second surface of the bicone are spaced apart to form a gap;
a cone comprising a second stepped surface that is sloped at an angle from the horizontal, wherein the second stepped surface is configured to receive at least a third amount of the particulates received from the foreline, and wherein the cone is coupled to the bicone; and
a channel proximate the second stepped surface, wherein a gas may flow through the channel and the gap to react with the particulates disposed on the first and second stepped surfaces.

12. A method of processing a substrate in a deposition chamber, comprising:
depositing a layer on a substrate in a processing region of a deposition chamber, wherein by-products are produced in a foreline or a processing region of the deposition chamber during the process of depositing the layer;
catching a portion of the by-products in a processing region of a catchpot that is fluidically connected to the foreline; and
converting at least a portion of the by-products disposed in the catchpot to a gaseous phase by flowing a cleaning gas over a portion of the by-products disposed on an angled surface that is disposed in the processing region of the catchpot.

13. The method of claim 12, wherein the by-products comprise silicon-containing particles.

14. The method of claim 13, wherein the cleaning gas comprises nitrogen trifluoride (NF₃).

15. The method of claim 12, wherein catching a portion of the by-products further comprises:
receiving the portion of the of the by-products on the angled surface, wherein the angled surface has a slope relative to a horizontal plane.

16. The method of claim 12, wherein the catchpot comprises at least one interior surface, wherein the at least one interior surface has a slope relative to a horizontal plane which is substantially equal to or greater than the angle of repose of the by-products.

17. The method of claim 16, wherein catching the portion of the by-products further comprises disposing an amount of the by-products on the at least one interior surface which comprises at least one step.

18. The method of claim 12, wherein catching the portion of the by-products further comprises disposing an amount of the by-products on at least one interior surface which comprises at least one step, wherein the at least one step has a rise and a run which form a slope having an angle substantially equal to or greater than the angle of repose of the by-products disposed over at least a portion of the at least one step.

19. The method of claim 12, further comprising cooling the angled surface using a cooling system.

20. The method of claim 12, wherein flowing the cleaning gas comprises flowing the cleaning gas at a rate of about 160 sccm per cubic centimeter of volume of the processing region of the catchpot.
